(19) United States
(12) Patent Application Publication
(10) Pub. No.: US 2026/0147065 A1
(43) Pub. Date: May 28, 2026

(54) METHOD AND APPARATUS FOR CARRYING OUT PROTECTIVE EARTH MONITORING ON ELECTRICAL INSTALLATIONS OR ELECTRICAL DEVICES

(71) Applicant: FRESENIUS MEDICAL CARE DEUTSCHLAND GMBH, Bad Homburg (DE)

(72) Inventors: Matthias KLOTZ, Bad Homburg (DE); Rene LUCK, Bad Homburg (DE)

(73) Assignee: FRESENIUS MEDICAL CARE DEUTSCHLAND GMBH, Bad Homburg (DE)

(21) Appl. No.: 19/130,964

(22) PCT Filed: Nov. 21, 2023
(86) PCT No.: PCT/EP2023/082478

§ 371 Date: May 19, 2025

(30) Foreign Application Priority Data
Nov. 23, 2022 (DE) 10 2022 131 027.2

(51) Int. Cl. G01R 31/66

(52) U.S. Cl. CPC G01R 31/66

(57) ABSTRACT

The present invention is in the area of checking the proper condition of the protective conductor connection of electrical installations or electrical apparatuses and in particular medical apparatuses. Devices and methods are proposed which assess the quality of a protective conductor connection on the basis of the signal transmission of a uniquely coded electrical signal, wherein the signal transmission takes place with incorporation of the protective conductor connection by coupling at least two conductors.

### TECHNICAL AREA

The present invention is in the area of checking the proper condition of the protective conductor connection of electrical installations or electrical apparatuses and in particular medical apparatuses.

### BACKGROUND

Electrical apparatuses, in which there is the possibility that a person will come into physical contact with voltage-carrying parts of the apparatus, are subject to special requirements. This is the case in particular for medical apparatuses. To prevent high electrical voltages from being applied, for example, in the event of a fault, to a device part which is potentially touchable by a person or to minimize the amperage of the electrical current which flows through the body of a person for this case, it is often provided that such electrically conductive device parts are connected at low electrical resistance to the protective conductor (PE) of the electrical installation, which is at earth potential. For medical apparatuses and in particular for such apparatuses in which a patient at least indirectly forms a conductive connection with the medical device via an extracorporeal blood circulation, the presence of a protective conductor connection is of particular importance.

In haemodialysis apparatuses, a conductive dialysis liquid which is pumped by the dialysis device is guided past the blood of the patient, which is also pumped by the dialysis device in an extracorporeal blood circulation, via a semipermeable membrane in the dialysis filter. In addition to the contact at the membrane, there are often still further liquid connections from the dialysis device to the blood of the patient, for example via dilution liquids, which are added to the patient blood via corresponding fluid connections. The blood in the extracorporeal blood circulation is withdrawn from the patient via cannulas, filtered in the dialysis process, and returned again. The access to the vascular system of the patient generally takes place in this case for patients requiring chronic dialysis via a surgically produced connection between an artery and a vein in the arm of the patient, a so-called fistula, which enables sufficiently high blood flows.

In the case of acute dialysis treatments, such a fistula is not yet present. In these cases, the access to the vascular system of the patient is enabled via a so-called central venous catheter, the end of which is located in spatial proximity to the heart of the patient.

If a contact of the dialysis liquid with an electrical voltage occurs due to an event of a fault, in both cases there is an electrically conductive connection between dialysis liquid and vascular system of the patient and thus the risk of serious hazard to the patient, in particular in the case of acute dialysis and the accompanying proximity of the central venous catheter to the heart of the patient.

To minimize this hazard, protective devices can be provided, via which a connection having good conductivity is produced from the dialysate to the protective conductor of the electrical installation. In the event of a fault, electrical currents are thus primarily discharged via this connection and not via the vascular system of the patient. Additional protective elements, such as fault-current circuit breakers and electrical fuses, also offer protection from an electrical shock (so-called earth short-circuit). The fault currents recognized by fault-current circuit breakers are generally orders of magnitude higher than the discharge currents tolerable for the special application in dialysis machines, however.

It is therefore important for the operational safety of apparatuses which have a protective conductor connection that the protective conductor connection is continuously present and electrically conducts as well as possible. For the above-mentioned medical apparatuses and in particular for dialysis apparatuses, the proper connection to the protective conductor of the electrical installation is accordingly particularly important.

### SUMMARY OF THE INVENTION

It is therefore the object of the present invention to provide a device and a method for checking the proper electrical connection of an apparatus, in particular a medical apparatus, to the protective conductor of the electrical installation.

This object is achieved by a device according to claim 1 and a method according to claim 11. The dependent claims describe advantageous embodiments of the invention.

Accordingly, a device is proposed for checking the protective conductor connection of an electrical installation 101 or an electrical apparatus 100, 105, which is configured for electrical connection to an electrical installation 101, wherein the electrical apparatus has at least one conductor A and one conductor B, wherein the conductor A is at least indirectly electrically connectable to a conductor C of the electrical installation, and wherein the conductor B is at least indirectly electrically connectable to a conductor D of the electrical installation, wherein the conductor C is the protective conductor, and wherein the electrical connection of the electrical apparatus to the electrical installation optionally takes place by means of an electrical mains supply line 105, which has at least one conductor E and one conductor F, wherein the conductor E is connectable to the conductor A and the conductor C, and wherein the conductor F is connectable to the conductor B and the conductor D.

The proposed device furthermore comprises a coupling device 102 for coupling a uniquely coded electrical signal at a coupling point into a first conductor, selected from the conductors of a first group A, C, E or a second group B, D, F.

The proposed device furthermore comprises a receiving device 103, which is configured to receive the coded signal at a reception point on the second conductor if the coded signal is transmitted on the second conductor by a transmitting device 106, which is configured to transmit the signal coupled into the first conductor at least indirectly on the second conductor at a transmission point, wherein the second conductor is selected from the other group than the group of the first conductor. The proposed device furthermore comprises an evaluation device 104, which is configured to assess the quality of the protective conductor connection on the basis of the signal received by the receiving unit 103.

Furthermore, a method is proposed for checking the protective conductor connection of an electrical installation 101 or an electrical apparatus 100, 105, which is configured for electrical connection to an electrical installation 101, wherein the electrical apparatus 100 has at least one conductor A and one conductor B, wherein the conductor A is at least indirectly electrically connectable to a conductor C of the electrical installation 101, and wherein the conductor B is at least indirectly electrically connectable to a conductor D of the electrical installation 101, wherein the conductor C is the protective conductor, and wherein the electrical connection of the electrical apparatus to the electrical installation optionally takes place by means of an electrical mains supply line 105, which has at least one conductor E and one conductor F, wherein the conductor E is connectable to the conductor A and the conductor C, and wherein the conductor F is connectable to the conductor B and the conductor D.

The proposed method comprises the steps of coupling a uniquely coded electrical signal at a coupling point into a first conductor, selected from the conductors of a first group A, C, E or a second group B, D, F, at least indirectly transmitting the coupled signal at a transmission point from the first to a second conductor, wherein the second conductor is selected from the other group than the group of the first conductor, receiving the coded signal at a reception point on the second conductor, and assessing the quality of the protective conductor connection on the basis of the signal received by the receiving unit.

The proposed devices and methods are thus based on assessing the quality of a protective conductor connection on the basis of the signal transmission of a uniquely coded electrical signal, wherein the signal transmission takes place with incorporation of the protective conductor connection by a coupling of at least two conductors.

The present invention is especially applicable for checking the protective conductor connection for a dialysis apparatus, as an example of an embodiment of a medical apparatus and an electrical apparatus. As described above, the proper condition of the protective conductor connection is particularly important in dialysis apparatuses. The devices and methods according to the invention are suitable, however, for checking the proper condition of the protective conductor connection for any electrical apparatus or any device which is provided for a protective conductor connection to an electrical installation, or the protective conductor connection of the electrical installation itself.

### BRIEF DESCRIPTION OF THE DRAWINGS

Further details and aspects of the present devices and methods will be described in more detail on the basis of, among other things, exemplary embodiments illustrated in the drawings.

In the figures:

FIG. 1 shows an exemplary illustration of an embodiment of the device according to the invention;

FIG. 2 shows a further exemplary illustration of an embodiment of the device according to the invention;

FIG. 3 shows a further exemplary illustration of an embodiment of the device according to the invention;

FIG. 4 shows an exemplary illustration of an embodiment of a mains supply line according to the invention; and

FIG. 5 shows an exemplary illustration of embodiments for circuits which are suitable for embodying the invention.

### DETAILED DESCRIPTION OF AN EXEMPLARY EMBODIMENT

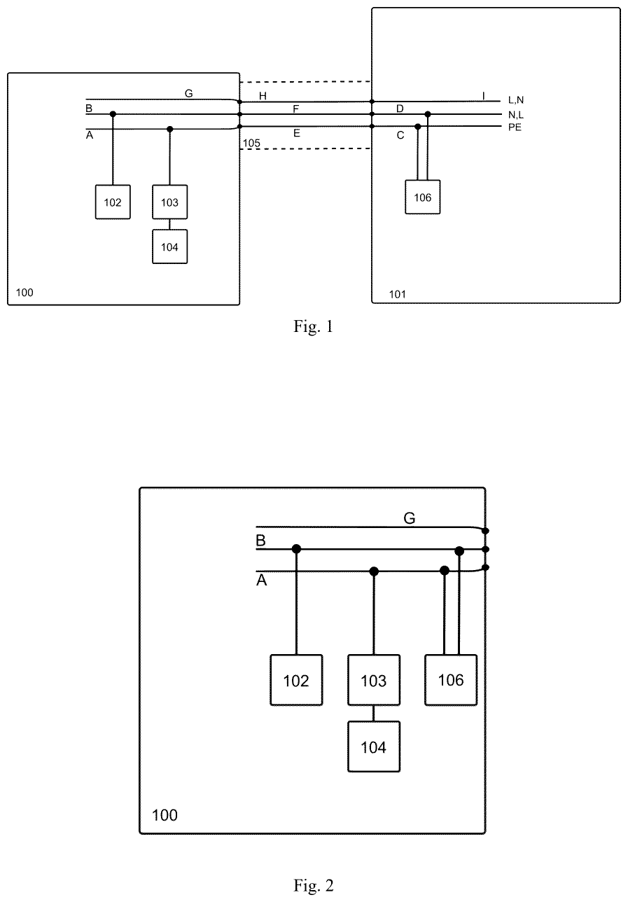

FIG. 1 shows an exemplary illustration of an embodiment of the device according to the invention. The electrical apparatus 100 comprises in this exemplary embodiment, for the supply with electrical energy, three conductors A, B, and G, which are at least indirectly connectable to the conductors C, D, and I of an electrical installation which provides the electrical energy.

In general, electrical apparatuses which have a protective conductor connection are provided with three conductors for connection to an electrical installation, namely a voltage-carrying conductor (L), a neutral conductor (N), and the protective conductor (PE). The embodiment for electrical installations also known as “classic zeroing”, in contrast, has only two conductors, namely the voltage-carrying conductor (L) and a combined protective conductor/neutral conductor (PEN). This type of electrical installation is no longer typical. For the further explanation of the invention, it is not essential whether the electrical apparatus 100 and the electrical installation 101 have two conductors or three conductors for the energy supply. In contrast, it is essential that the electrical apparatus 100 is provided for connection to the protective conductor or the combined protective conductor/neutral conductor (PE or PEN). The term protective conductor is to stand hereinafter for both the PE conductor of a three-pole electrical installation and for the PEN conductor of a two-pole electrical installation.

When the term “conductor” is used hereinafter, it means an electrical conductor, in particular a cable. When a conductor is described hereinafter as electrically connected to another conductor, this means a low-resistance electrical connection of the two conductors, for example, by corresponding plug contacts, screw connection, soldering, crimping, welding, or the like, if not described otherwise.

In the exemplary embodiment of FIG. 1, the connection of the conductors A, B, and G to the conductors C, D, and I of the electrical installation takes place indirectly via a mains supply line 105, which is also embodied as three-pole having the conductors E, F, and H.

Such a mains supply line can be embodied as pluggable, for example on the device side using a so-called cold-device plug connection, which fits in a corresponding counterpart of the electrical apparatus 100, and on the mains side via a safety plug, which fits in a typical socket, for example a wall socket.

It can also be provided that the mains supply line 105 (shown by dashed lines in FIG. 1) is fixedly connected on the device side to the electrical apparatus 100. Furthermore, it can be provided that the electrical apparatus is directly connected or connectable to the electrical installation without dedicated mains supply line 105. This is the case in particular with fixedly installed electrical apparatuses, in particular with apparatuses installed in the wall.

In any case, the conductor A of the electrical apparatus 100 is at least indirectly electrically connectable to the conductor C, and the conductor B of the electrical apparatus 100 is at least indirectly electrically connectable to the conductor D. The electrical connection can be established via the mains supply line 105, wherein a connection of the conductors A to E and E to C and the conductors B to F and F to D takes place, or directly without dedicated electrical supply line 105, thus A with C and B with D.

For the sake of completeness, it is to be noted that the conductor G, if present, can also be connected via the conductor H of the mains supply line to the conductor I of the electrical installation, or directly thereto, without dedicated mains supply line.

It is essential that the conductor C of the electrical installation is the protective conductor.

The device according to the invention comprises a coupling device 102 for coupling a uniquely coded electrical signal at a coupling point into a first conductor, selected from the conductors of the first group A, C, E or the second group B, D, F. In the exemplary embodiment according to FIG. 1, the coupling device 102 couples into the conductor B of the electrical apparatus 100 at the point identified by a black circle. The uniquely coded electrical signal can be an arbitrary, preferably digitally coded signal. The coding can uniquely identify the electrical apparatus 100. For example, the coding can code a serial number which uniquely identifies the electrical apparatus. The type of the digital coding is not essential in this case. It is only important that the coding is suitable for coupling into one of the conductors A, B, C, D, E, F and for transmission by means of the transmission device 106 to a respective other conductor of the conductors A, B, C, D, E, F. As an exemplary embodiment for such a coding, a sequential digital signal is conceivable having a sufficiently high amplitude (for example 5 V or 12 V) and a fixed cycle, which represents a specific sequence of digital “zero” and “one” symbols, where the sequence forms a unique coding. In a refinement, the sequential digital signal is modulated onto a periodic analogue carrier signal, for example, onto a sine signal having a frequency greatly differing from the mains frequency, for example 10 kHz.

Another embodiment can also comprise a frequency coding, in which a periodic signal is switched on and off with a fixed cycle at preferably a frequency clearly distinguishable from the mains frequency, wherein the switched-on signal symbolizes a digital “one” and the switched-off signal a digital “zero”. A person skilled in the art knows further embodiments for suitable signal codings, for example FSK (frequency shift keying) or PSK (phase shift keying).

The uniquely coded electrical signal can also be an analogue signal, for example, a sinusoidal signal of a specific frequency which stands out clearly from the mains frequency.

The coupling of the uniquely coded electrical signal takes place into a first conductor selected from the conductors of a first group A, C, E or a second group B, D, F.

In the exemplary embodiment of FIG. 1, the feed takes place into the conductor B, thus a conductor of the electrical apparatus 100, wherein the conductor B is associated according to the invention with the second group B, D, F.

The transmission device 106 is configured to transmit the signal coupled into the first conductor at a transmission point to a second conductor, wherein the second conductor is selected from the other group than the group of the first conductor, in the present example of FIG. 1 thus in a conductor of the first group A, C, E.

In the exemplary embodiment of FIG. 1, the transmission from the conductor D to the conductor C takes place at a transmission point which is assigned to the electrical installation.

According to the invention, the conductor C is the protective conductor of the electrical installation. Accordingly, the conductors A and E are provided for the at least indirect connection to the protective conductor of the electrical installation.

Such a transmission point can be positioned, for example, in the fuse box of the electrical installation 101, or in the domestic junction box, which connects the building in which the electrical installation is located to the public supply network.

The electrically coded signal, which is coupled into the conductor B in the exemplary embodiment of FIG. 1, is applied, when the electrical apparatus is properly connected, via the mains supply line 105 using the conductor F to the electrical installation 101 at the conductor D and is transmitted by the transmission device 106 to the conductor C.

The transmission device is configured in such a way that it can transmit the uniquely coded electrical signal from any arbitrary conductor to any arbitrary other conductor. The transmission can take place capacitively in this case through a capacitor or inductively through an electrical transformer, in which the two transformer coils are each in the signal path of the two conductors, or also resistively through a resistor which connects the two conductors. Arbitrary combinations of the above-mentioned devices are also conceivable. In one preferred embodiment, the transmission takes place through a capacitor which capacitively connects the first conductor to the second conductor, for example a so-called Y capacitor having sufficient dielectric strength and, for example, a capacitance of 4.7 nF. The capacitance of the capacitor is selected so that the unique coded electrical signal is transmitted as well as possible, but the mains frequency of the mains is blocked as much as possible. The higher the (carrier) transmission frequency of the uniquely coded electrical signal, the smaller can the coupling capacitor be selected.

In the exemplary embodiment of FIG. 1, by way of example the conductors D and C are capacitively connected to one another by an above-mentioned capacitor, for example, due to which the uniquely electrically coded signal, which is applied in the correct case on the conductor D, is transmitted to the conductor C. Depending on the transmission device and embodiment thereof, a more or less strong damping of the signal takes place here, which can be computed or measured. The amplitude of the transmitted signal which is applied on the conductor C is thus characteristic for the correct case. This is not significantly changed by a proper, i.e., correct electrical connection via the conductors E and A.

The transmitted uniquely coded electrical signal is thus also applied on the conductor A, where it is received or decoupled by the receiving device 103 and supplied to an evaluation device 104.

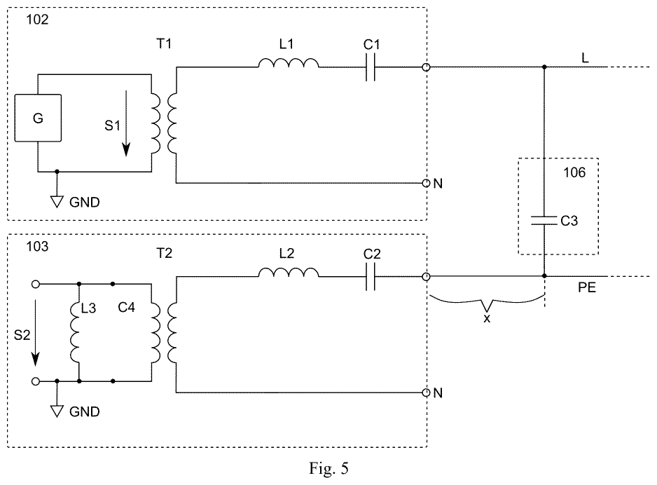

The coupling and decoupling of the uniquely coded electrical signal by the coupling device 102 and the receiving device 103 can take place arbitrarily, but in particular capacitively by capacitors and/or inductively by electrical transformers. A person skilled in the art can make use of the known embodiments of so-called power line communication (PLC) for this purpose. Direct coupling of the uniquely coded electrical signal via an ohmic connection is also likewise conceivable, for example via a high-ohm resistor or a high-ohm resistor network. FIG. 5 shows possible embodiments for the devices 102 and 103.

The evaluation unit 104 checks the signal supplied thereto and infers the quality of the protective conductor connection on the basis of the check.

According to the invention, the quality of the protective conductor connection means the quality of the electrical connection which the conductors or conductor connections have, which are provided for connection to the protective conductor of the electrical installation.

In the exemplary embodiment of FIG. 1, a signal transmission takes place from the coupling point in the electrical apparatus in the conductor B, via the conductor F of the mains supply line 105 and the conductor D of the electrical installation 101 and from there via the transmission device 106, the conductor C of the electrical installation 101, the conductor E of the mains supply line 105 to the conductor A of the electrical apparatus 100.

According to the invention, the conductor C is the protective conductor, accordingly with normal three-pole supply, the conductor D is the neutral conductor N or the voltage-carrying conductor L, and the conductor I of the electrical installation is accordingly the voltage-carrying conductor L or the neutral conductor N. For the devices and methods according to the invention, the conductors D and I of the electrical installation are exchangeable.

An event of a fault in the neutral conductor or in the voltage-carrying conductor, for example an interruption, would have an effect directly in the function of the electrical apparatus. An interruption of the connection to or in the protective conductor of the electrical installation normally remains unnoticed, however.

An interruption of the conductors, which are provided for the connection to the protective conductor of the electrical installation, which is in the signal path of the coupled signal (thus from the corresponding conductor up to the transmission point) can be detected using the present invention by contrast in that no signal is detected at the reception point. The evaluation device 104 accordingly infers an interruption of the protective conductor connection due to the absent signal and can output a corresponding signal or initiate further measures.

A deficient quality of the protective conductor connection can also be recognized. This can exist if the electrical connection has excessively high resistance, for example due to improper or defective plug connections or other electrical connections, such as screw connections, soldered connections, welds, or crimped connections. Corrosion can also be a cause of a protective conductor connection having excessively high resistance and/or can result in parasitic effects, which impair the signal transmission of the uniquely coded electrical signal from the coupling point to the reception point. This impairment can have an effect in increased damping of the decoupled signal and/or in an unexpected phase shift.

Accordingly, the evaluation device 104 can conclude problems in the protective conductor connection not only on the basis of an absent signal, but also on the basis of an excessively low amplitude or an unexpected signal profile. In practice, a very small uniquely coded electrical signal is often also detected with interrupted protective conductor connection due to parasitic capacitive coupling of the mains conductors with one another. When reference is made hereinafter to a uniquely coded electrical signal not being able to be detected, this also comprises according to the invention that only a very small amplitude, for example less than 10%, 5%, or 1% of the amplitude of the coupled uniquely coded electrical signal can be detected.

The uniquely coded signal is characteristic of the electrical device, the protective conductor connection of which is to be checked, for example of the electrical apparatus 100 or the electrical installation 101.

It is thus ensured that interference or secondary signals of further devices according to the invention, which are coupled into the protective conductor of the electrical installation via possibly also undesired coupling processes, are not inadvertently used for the assessment, because the uniquely coded electrical signal can be assigned uniquely to an electrical device to be checked.

The evaluation device 104 is configured in such a way that it decodes an electrical signal which is transmitted to it from the decoupling device 103, i.e., recognizes the information content of the coded signal, in order to check whether the signal is assigned to the electrical device to be checked. Furthermore, the evaluation device 104 is configured so as to detect at least one signal parameter of the electrical signal, which is transmitted to it from the decoupling device 103. Such a signal parameter is, for example, the signal amplitude and/or the signal profile. The evaluation device 104 is configured so as to compare the acquired signal parameter to an expected signal parameter value, which is present with a proper protective conductor connection of the electrical device to be checked or the electrical apparatus to be checked, and to initiate further measures in dependence on this comparison.

Such a measure can include outputting a signal, for example can be arranged to output a warning on a display or to output a warning tone, in the event of a deviation of the detected signal parameter from the expected signal parameter which exceeds a minimum amount. A further measure can be activating a disconnecting device, for example an electrical disconnecting relay, which electrically disconnects the electrical device to be checked from a connection to the electrical installation, so that the electrical device to be checked is switched to nonfunctional and deenergized.

In the exemplary embodiment according to FIG. 1, the components 102, 103, and 104 are positioned inside the electrical apparatus 100 or are parts of the electrical apparatus 100. It is not essential for the invention where these components are located or whether they are part of the electrical apparatus 100 or are at least partially not part of the electrical apparatus 100, or form an independent unit.

The placement of the transmission device 106 takes place at a point in the observed electrical system such that a statement can be made about the protective conductor connection of the desired electrical device or the electrical apparatus or a combination of electrical devices and apparatuses. Accordingly, the transmission of the uniquely coded electrical signal is carried out at least indirectly by the transmission device 106 at a transmission point on the second conductor according to the invention. This means that the uniquely coded electrical signal is coupled into the first conductor according to the invention and is transmitted directly by it, or indirectly by a conductor electrically connected to this conductor by the transmission device 106 on the second conductor. This transmission on the second conductor can take place at the transmission point immediately directly onto the second conductor, or indirectly in that the transmission device 106 transmits the uniquely coded electrical signal onto a conductor electrically connected to the second conductor. The uniquely coded electrical signal is applied in both cases having specific minimum signal parameters on the second conductor as long as the system is correct.

In the example of FIG. 1, the coupling of the uniquely coded electrical signal takes place into the first conductor B according to the invention from the conductor group B, D, F. The uniquely coded electrical signal is also applied on the conductor D due to the electrical connections (conductor B to conductor F and conductor F to conductor D). At a transmission point on the conductor D, the transmission of the uniquely coded electrical signal by the transmission device 106 onto the conductor C takes place and thus indirectly onto the second conductor A according to the invention from the conductor group A, C, E, since there is an electrical connection between the conductor C and the conductor A (conductor C to conductor E and conductor E to conductor A).

The selection of the coupling point, the transmission point, and the reception point determines the length of the protective conductor connection which is to be checked, and also the instances (electrical apparatus 100, mains supply line 105, electrical installation 101), the protective conductors of which are or are to be electrically connected to one another, and also in which instance the respective devices configured for this purpose are present or are assigned thereto. It is thus possible by suitable selection of the coupling point, the transmission point, and the reception point to check the protective conductor connection of the electrical apparatus 100, the mains feed line 105, and the electrical installation 101 individually or in isolation, or the protective conductor connection of an arbitrary, also partial combination of electrical apparatus 100, mains feed line 105, and electrical installation 101.

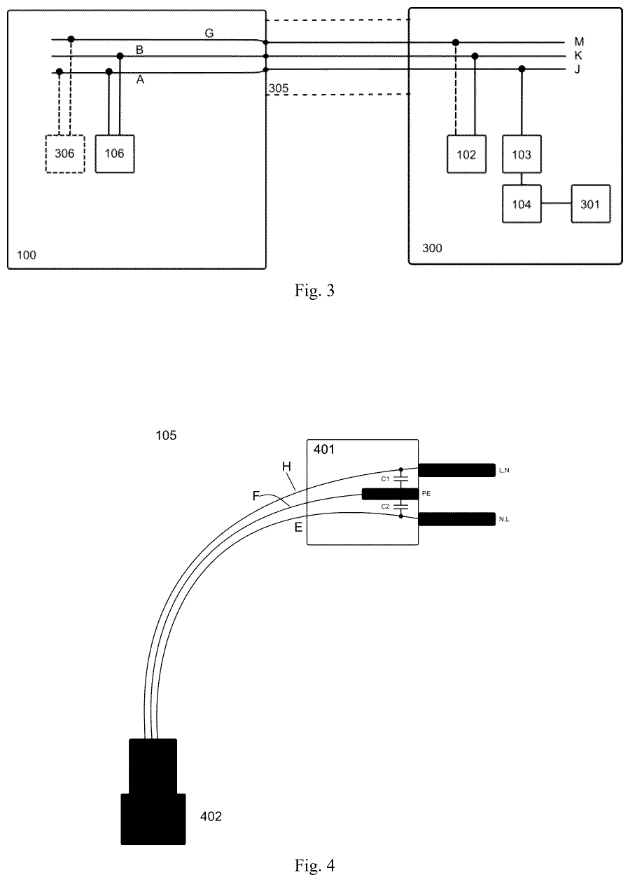

In the exemplary embodiment according to FIG. 2, the devices 102, 103, 104, and 106 are located inside the electrical apparatus 100.

Similarly to FIG. 1, the conductor A is provided for connection to the protective conductor of the electrical installation. The respective other conductors are accordingly connected to the voltage-carrying conductor L or to the neutral conductor N. In practice, it often cannot be predicted whether the respective other conductors B and G are connected to the voltage-carrying conductor L or to the neutral conductor N, since the mains plugs normally used for this purpose are connectable in two freely selectable positions to the mains socket, wherein the contacting of voltage-carrying conductor L and neutral conductor N of the electrical installation 101 to the conductors of the mains supply line is exchanged. It is solely ensured that independently of the orientation of the plug connection, the protective conductor is always connected to the conductor of the mains supply line provided for this purpose.

However, even with mains plug/mains socket combinations which only enable one possible plug position, it is not certain which pole of such a position is the neutral conductor or the voltage-carrying conductor. Only the protective conductor is also uniquely assigned to a pole in such embodiments.

The positioning of the transmission device 106 within the apparatus preferably takes place directly at the border of the apparatus housing, thus, for example, as a capacitor between the corresponding poles of a cold-device socket.

The method carried out analogously to FIG. 2 does not differ from the method according to the exemplary embodiment shown in FIG. 1. The single difference is in the positioning of the transmission device. In this exemplary embodiment, it can be checked whether the protective conductor connection is embodied properly to the pole of the cold-device socket provided for this purpose, or up to the transmission point, at which the transmission device 106 electrically couples the two conductors A and B to one another. The electrical supply of the components 102, 103, 104, 106 can be made available for this purpose from outside via the mains connection, however, the components can also be supplied independently of a mains connection of the electrical apparatus by a battery or accumulator supply.

It can also be provided that the components 102, 103, and 104 form an independent apparatus 300. This is shown in FIG. 3.

The apparatus 300 is equipped, for example, with a cable 305 connected on one side to the apparatus 300, comprising in this example three conductors, which are provided for connection to the conductors A, B, and G of an electrical apparatus 100. For this purpose, the cable can be equipped on one side with a plug connector matching with a socket of the electrical apparatus 100, for example with a cold-device plug, which is configured for connecting a cold-device socket of the electrical apparatus.

The coupling of the uniquely coded electrical signal takes place in this exemplary embodiment within the apparatus 300 using the coupling device 102 into the conductor K, which is provided for the connection to the conductor B of the electrical apparatus 100. Inside the electrical apparatus, the transmission of the uniquely coded electrical signal applied in the correct case on the conductor B using the transmission device 106 takes place from the conductor B to the conductor A. This conductor A is provided in normal operation for connection to the protective conductor of an electrical installation. The conductor A of the electrical apparatus 100 is connected to a conductor of the cable 305 and thus also to the conductor J of the apparatus 300.

The uniquely coded electrical signal can be received on this conductor J by the receiving device 103 and transferred to the evaluation device 104. This evaluates the received signal in the already described manner. The apparatus 300 furthermore advantageously comprises a signalling device 301, which signals the result of the assessment. This can be embodied as desired, for example as a display, on which a text message corresponding to the assessment is output, one or more corresponding light displays, a tone generator, or an interface which can communicate data outward.

As shown by dashed lines in FIG. 3, in addition a further transmission device 306 can be provided in the electrical apparatus 100, which is configured to transmit the uniquely coded electrical signal from the conductor G to the conductor A. This is to ensure that independently of the conductor onto which an apparatus 300 couples the uniquely coded signal, this signal is transmitted in the correct case on the conductor A, which is provided for connection to the protective conductor of the electrical installation.

Alternatively or additionally, it can be provided that in the apparatus 300, the uniquely coded signal is coupled onto two conductors K and M (see dashed connection originating from 102).

It is unimportant for the invention onto which conductor or conductors the uniquely coded electrical signal is coupled. It is only essential that a signal flow for the uniquely coded electrical signal takes place from the coupling point via at least one transmission point and the conductor of the electrical apparatus 100, which is provided for connection to the protective conductor of the electrical installation, to the reception point.

It is thus also possible in FIG. 3, for example, to couple the uniquely coded electrical signal onto the conductor J, and to receive it on one or two of the conductors K and M (not shown in FIG. 3).

The above-mentioned alternatives can be used for any disclosed embodiment, even if they are not explicitly shown in the figures.

It is also possible to check the proper protective conductor connection of the electrical installation. Similarly to FIG. 2, in this case one or two transmission devices within the electrical installation would be used, for example in the fuse box or in the domestic junction box. This is not restricted to a three-pole installation, rather according to the invention a transmission device can be provided from each pole of the electrical installation on the protective conductor pole. Optionally, the coupling device 102 can also be part of the electrical installation 101 or can be assigned thereto.

According to the invention, the term “electrical apparatus 100” is to be understood broadly. The mains supply line 105 can thus also be understood as an electrical apparatus.

FIG. 4 schematically shows a mains supply line 105 embodied as a cold-device cable, which has transmission devices according to the invention. In the exemplary embodiment of FIG. 4, the two capacitors C1 and C2 are shown as transmission devices, which function inside a safety plug 401, which is configured for connection to a mains socket, as transmission devices according to the invention. The embodiment having only one capacitor C1 or C2 is also conceivable. The capacitors C1 and C2 connect the protective contact PE to the respective other two poles L and N and are thus configured according to the invention for transmitting a coded electrical signal on the protective conductor connection. The conductor designation E, F, His analogous to FIG. 1.

Such a mains supply line can be fixedly connected to the electrical device or else can be pluggable (safety plug 401 and cold-device plug 402), as in the example shown in FIG. 4.

It can be provided that the plug connections are designed so that the connection between the electrical apparatus 100 and the mains supply line 105 does not correspond to a general norm, but rather is designed individually so that only mains supply lines which have transmission devices according to the invention are connectable to the electrical apparatus 100.

It can also be provided that mains supply lines are identified optically uniquely similarly to FIG. 4, so that the user receives an indication that the mains supply line 105 has the transmission device according to the invention.

According to the invention, the check of a protective conductor connection takes place in that a uniquely coded signal is coupled at a coupling point into a first conductor and is transmitted at a transmission point from the first conductor or from a conductor connected with good electrical conductivity to this first conductor in the correct case at least indirectly into a second conductor. Furthermore, the transmitted uniquely coded signal is received at a reception point on the second conductor and the received signal is checked. A transmission of the uniquely coded electrical signal thus takes place from a coupling point to a reception point via a transmission route. It is essential that the transmission route comprises the protective conductor connection to be checked. However, it is not essential in this case whether the first or second conductor or a conductor connected thereto with good conductivity in the correct case is the protective conductor. In other words, it is not essential whether coupling takes place into the protective conductor or into a conductor conducting well with it in the correct case or decoupling takes place from the protective conductor or from a conductor connected thereto with good conductivity in the correct case or reception takes place there.

A protective conductor connection is defined according to the invention in that a part of this connection is at least indirectly electrically connectable to the protective conductor of the electrical installation. According to the invention, the protective conductor of the electrical installation itself is also comprised by such a part.

The quality of the protective conductor connection is concluded in the already described manner in dependence on the check of the received signal.

Multiple protective conductor connections may accordingly be checked with the aid of the invention.

With reference to FIGS. 1 to 4, different protective conductor connections may be checked as follows:

The protective conductor connection of the electrical apparatus 100, in which, for example, a transmission device 106 is provided between the conductors A and B and coupling takes place into a conductor A or B and reception takes place on the respective other conductor. The transmission device 106 is advantageously attached directly at the housing boundary between the conductors A and B, for example at the poles of a mains socket of the electrical apparatus 100, to which a mains supply line 105 can be connected. In FIG. 2, such an embodiment is shown for the case that all components required for this purpose are part of the apparatus 100. Alternatively, only a part of the components required for this purpose can also be part of the apparatus 100, as shown in FIG. 3. In this case, the positioning of the transmission device advantageously does not take place at the poles of the mains socket of the electrical apparatus 100, but rather further in the interior of the apparatus to ideally check the entire length of the protective conductor connection in the apparatus. Furthermore, the protective conductor connection of an electrical apparatus having fixedly attached mains supply line 105 can be checked. In this case, the transmission device 106 is advantageously attached directly between the poles of the mains plug 401, as shown in FIG. 4. The coupling then takes place in that coupling occurs into one conductor A or B of the electrical apparatus 100 and reception occurs on the respective other conductor. It is thus checked whether the protective conductor connection of the electrical apparatus is embodied properly up to the transmission point in the mains supply line 105, thus in the given example up to the contacting in the mains plug 401.

Furthermore, the protective conductor connection of a mains supply line 105 embodied as pluggable can be checked. In this case, the mains supply line is advantageously embodied as in FIG. 4. The coupling then takes place with an apparatus 300 configured accordingly for this purpose similarly to FIG. 3, with the difference that instead of the apparatus 100, a mains supply line 105 is connected to the apparatus 300, as in FIG. 4.

Furthermore, the protective conductor connection of an electrical installation 101 can be checked. The transmission device 106 is accordingly provided, for example, between the conductors C and D as shown in FIG. 1. The coupling and the reception of the uniquely coded electrical signal then takes place similarly to FIG. 3, for example, with the difference that instead of the apparatus 100, an electrical installation 101 is connected to the apparatus 300. This can thus be implemented, for example, in that the conductors J, K, and M of the apparatus are at least indirectly connectable for connection to a mains socket using a mains plug. Other connectors for contacting electrical contacts such as terminals or probe tips are also possible.

FIG. 5 shows by way of example schematic embodiments for a coupling device 102, a receiving device 103, and a transmission device 106 (each outlined by dashed lines).

The coupling device is formed by the transformer T1, the coil L1, and the capacitor C1. The signal generator G generates the uniquely coded electrical signal, which is applied as S1 on the primary side of the transformer T1. This signal is transmitted via the transformer T1 to the secondary side of Tl and coupled onto the conductor L. The conductor L is in this exemplary embodiment the first conductor according to the invention and is a conductor which is at least indirectly connectable to the voltage-carrying conductor L of the electrical installation. The series circuit of L1 and C1 forms a bandpass, which is dimensioned so that the mains frequency of the electrical installation is damped and loads the transformer little or not at all, but the frequency of the signal S1 is dimensioned so that it is damped as little as possible by this bandpass.

Via the capacitor C3, which is an embodiment of a transmission device 106 according to the invention, the uniquely coded signal coupled onto the conductor L is transmitted to a conductor PE, which is at least indirectly connectable to the protective conductor PE of the electrical installation. In this exemplary embodiment, the conductor PE is the second conductor according to the invention.

Via the series circuit of L2 and C2, which form a bandpass in the same manner as L1 and C1, and the transformer T2, the signal transmitted on the conductor PE is transmitted on the secondary side of the transformer T2. The optional parallel circuit of L3 and C4 ensures a further suppression of frequencies there which does not correspond to the (carrier) frequency of the uniquely coded electrical signal. The component values of the coil L1, L2 and the capacitors C1 and C2 are dimensioned so that the (carrier) frequency of the uniquely coded electrical signal is damped as little as possible, but the mains frequency is damped as well as possible. A person skilled in the art makes use in this case of computation or simulation methods routine to him. Accordingly, a signal S2 is applied on the secondary side which has the unique coding of the signal S1 if the protective conductor connection (PE) is embodied properly between the transmission point and the reception point (in FIG. 5 identified as route x). If the protective conductor connection is interrupted on this route x, for example, no or only a very small signal S2 is detected. An evaluation circuit 104 then infers a protective conductor interruption and can initiate the already described measures, such as isolating the electrical apparatus which is assigned to the protective conductor connection or outputting an alarm message. A conductor connection having excessively high resistance on the route x also has an effect on signal parameters of the signal S2 in the already described manner.

1. A device for checking the protective conductor connection of an electrical installation or an electrical apparatus, which is configured for electrical connection to the electrical installation, wherein the electrical apparatus has at least one conductor A and one conductor B, wherein the conductor A is at least indirectly electrically connectable to a conductor C of the electrical installation, and wherein the conductor B is at least indirectly electrically connectable to a conductor D of the electrical installation, wherein the conductor C is the protective conductor,
and wherein the electrical connection of the electrical apparatus to the electrical installation optionally takes place by means of an electrical mains supply line, which has at least one conductor E and one conductor F, wherein the conductor E is connectable to the conductor A and the conductor C, and wherein the conductor F is connectable to the conductor B and the conductor D, said device comprising:
a coupling device for coupling a uniquely coded electrical signal at a coupling point into a first conductor selected from the conductors of the first group A, C, E or the second group B, D, F,
a receiving device, which is configured to receive the coded signal at a reception point on a second conductor if the coded signal is transmitted to the second conductor by a transmission device, which is configured to transmit the signal coupled into the first conductor at a transmission point at least indirectly to the second conductor, wherein the second conductor is selected from the other group than the group of the first conductor,
an evaluation device, which is configured to assess the quality of the protective conductor connection on the basis of the signal received by the receiving device.

2. The device according to claim 1, said device having a disconnecting device, wherein the device is configured to disconnect an electrical connection between the electrical apparatus and the electrical installation by means of the disconnecting device if the evaluation device assesses the quality of the protective conductor connection as inadequate.

3. The device according to claim 1, wherein the transmission device transmits the coded electrical signal through a capacitive coupling.

4. The device according to claim 1, wherein at least the coupling device and the evaluation device are parts of the electrical apparatus, or according to which the coupling device is part of the electrical installation or is assigned thereto.

5. The device according to claim 4, wherein the device is a medical apparatus.

6. The device according to claim 5, wherein the medical apparatus is embodied as a blood treatment apparatus and is configured for haemodialysis, for haemofiltration, for haemodiafiltration, for plasmapheresis, or for automatic peritoneal dialysis.

7. The device according to claim 1, wherein the device is configured so that the coded electrical signal is a digitally coded electrical signal.

8. The device according to claim 1, further, comprising a signalling device configured to output at least one signal dependent on the assessment of the evaluation device on the signalling device.

9. Use of a coupling device, evaluation device, isolating device, transmission device in the device according to claim 1.

10. An electrical mains supply line for use in the device according to claim 1, comprising at least one transmission device.

11. A method for checking the protective conductor connection of an electrical installation or an electrical apparatus, which is configured for electrical connection to an electrical installation, wherein the electrical apparatus has at least one conductor A and one conductor B, wherein the conductor A is at least indirectly electrically connectable to a conductor C of the electrical installation, and wherein the conductor B is at least indirectly electrically connectable to a conductor D of the electrical installation, wherein the conductor is the protective conductor,
and wherein the electrical connection of the electrical apparatus to the electrical installation optionally takes place by means of an electrical mains supply line, which has at least one conductor E and one conductor F, wherein the conductor E is connectable to the conductor A and the conductor C, and wherein the conductor F is connectable to the conductor B and the conductor D, said method comprising the steps:
coupling a uniquely coded electrical signal at a coupling point into a first conductor selected from the conductors of the first group A, C, E or the second group B, D, F,
at least indirectly transmitting the coupled signal at a transmission point from the first to a second conductor, wherein the second conductor is selected from the other group than the group of the first conductor,
receiving the coded signal at a reception point on the second conductor,
assessing the quality of the protective conductor connection on the basis of the signal received by the reception unit.

12. The method according to claim 11, said method further having the step:
disconnecting the electrical connection between electrical apparatus and the electrical installation if the quality of the protective conductor connection from the coupling point to the reception point is assessed as inadequate.

13. The method according to claim 11, wherein the coded electrical signal is capacitively transmitted.

14. The method according to claim 11, wherein at least the coupling and reception of the coded electrical signal and the assessment of the quality of the protective conductor connection are carried out by devices which are parts of the electrical apparatus, or according to which the coupling of the coded electrical signal is carried out by a device which is part of the electrical installation.

15. The method according to claim 11, wherein the coded electrical signal is generated as a digitally coded electrical signal.

16. The method according to claim 11 further comprising the step of outputting at least one signal dependent on the assessment.
